(19) United States
(12) Patent Application Publication
(10) Pub. No.: US 2026/0129787 A1
(43) Pub. Date: May 7, 2026

(54) VERTICALLY INTEGRATED FUEL CELL SYSTEM AND DATA CENTER SERVER RACKS

(71) Applicant: Bloom Energy Corporation, San Jose, CA (US)

(72) Inventors: Razvan PANATI, Atlanta, GA (US); Prasad PMSVVSV, Sunnyvale, CA (US); Chad PEARSON, Kirkland, WA (US); Carl COTTULI, Franklin, MA (US)

(21) Appl. No.: 19/380,239

(22) Filed: Nov. 5, 2025

Related U.S. Application Data
(60) Provisional application No. 63/717,510, filed on Nov. 7, 2024.

(51) Int. Cl. H05K 7/14; H01M 8/2475; H01M 8/249; H01M 16/00; H02J 3/02; H05K 7/20

(52) U.S. Cl. CPC H05K 7/1497; H01M 8/2475; H01M 8/249; H01M 16/003; H02J 3/02; H05K 7/1488; H05K 7/1498; H05K 7/20827; H02J 2101/30; H02J 2105/425

(57) ABSTRACT

A system includes a multi-level structure, a fuel cell power generation system including a plurality of power modules and at least one step load module containing supercapacitors located on at least one level of the multi-level structure, and a data center located on the at least one level of the multi-level structure and electrically connected to the fuel cell power generation system.

### FIELD

The present disclosure is generally directed to vertically integrated fuel cell systems and data center servers.

### BACKGROUND

Rapid and inexpensive installation can help to increase the prevalence of electrochemical systems, such as fuel cell systems. Installation costs for pour-in-place custom designed concrete pads, which generally require trenching for plumbing and electrical lines, can become prohibitive. Installation time is also a problem in the case of most sites since concrete pours and trenches generally require one or more building permits and building inspector reviews.

Furthermore, stationary fuel cell systems may be installed in a location where the cost of real estate is quite high or the available space is limited (e.g., a loading dock, a narrow alley or space between buildings, etc.). The system installation should have a high utilization of available space. When a considerable amount of stand-off space is required for access to the system via doors and the like, installation real estate costs increase significantly.

When the number of fuel cell systems to be installed on a site increases, one problem which generally arises is that stand-off space between these systems is required (to allow for maintenance of one unit or the other unit). The space between systems is lost in terms of its potential to be used by the customer of the system.

In the case of some fuel cell system designs, these problems are resolved by increasing the overall capacity of the monolithic system design. However, this creates new challenges as the size and weight of the concrete pad required increases. Therefore, this strategy tends to increase the system installation time. Furthermore, as the minimum size of the system increases, the fault tolerance of the design is reduced.

The fuel cell stacks or columns of these systems are usually located in hot boxes (i.e., thermally insulated containers). The hot boxes of existing large stationary fuel cell systems are housed in cabinets, housings or enclosures.

### SUMMARY

According to various embodiments, a system includes a multi-level structure, a fuel cell power generation system including a plurality of power modules and at least one step load module containing supercapacitors located on the at least one level of the multi-level structure, and a data center located on the at least one level of the multi-level structure and electrically connected to the fuel cell power generation system.

According to various embodiments, a system includes a fuel cell power generation system; a data center comprising server racks containing servers and power shelves; at least one direct current (DC) power distribution unit (PDU) that electrically connects the fuel cell power generation system to the power shelves of the server racks of the data center; and at least one alternating current (AC) PDU that electrically connects the fuel cell power generation system to AC powered auxiliary components of the data center.

### BRIEF DESCRIPTION OF THE DRAWINGS

FIG. 1 is a perspective view of a modular fuel cell system according to various embodiments of the present disclosure.

FIG. 2 is top plan view of a modular fuel cell system according to various embodiments of the present disclosure.

FIG. 3 is a perspective view showing an electrochemical cell system including a plurality of modules located on a skid, according to various embodiments of the present disclosure.

FIG. 4A illustrates a perspective view of an electrochemical cell system according to various embodiments of the present disclosure.

FIG. 4B illustrates top plan view of the electrochemical cell system of FIG. 4A.

FIG. 4C illustrates a schematic view of a skid of FIG. 4A.

FIG. 5A is a perspective view of a multilevel structure comprising vertically integrated electrochemical cell systems, according to various embodiments of the present disclosure.

FIG. 5B is a schematic top view showing one floor of the structure of FIG. 5A.

FIG. 5C is a schematic top view showing structural elements of a bay of the floor of FIG. 5B.

FIG. 5D is a schematic side view showing an exhaust conduit of the structure of FIG. 5A.

FIG. 5E is a schematic side cross-sectional view of the multilevel structure including an alternate exhaust duct configuration, according to various embodiments of the present disclosure.

FIG. 6 is system block diagram of a power generation unit coupled with a data center, according to various embodiments of the present disclosure.

FIG. 7A is a schematic top view showing one level of one floor of a combined structure for an electrochemical system and data center, according to various embodiments of the present disclosure.

FIG. 7B is a schematic top view showing another level of one floor of a combined structure for an electrochemical system and data center of FIG. 7A, according to various embodiments of the present disclosure.

FIG. 7C is a schematic top view showing another floor of a combined structure for electrochemical system and data center, according to various embodiments of the present disclosure.

FIG. 8A is a schematic side view showing the levels and floors of FIG. 7A, 7B, 7C of a combined structure for an electrochemical system and data center, according to various embodiments of the present disclosure.

FIG. 8B is a schematic side view showing an exhaust conduit of the structure of FIG. 8A.

### DETAILED DESCRIPTION

It is to be understood that both the foregoing general description and the following detailed description are exemplary and explanatory only and are not restrictive of the invention as claimed.

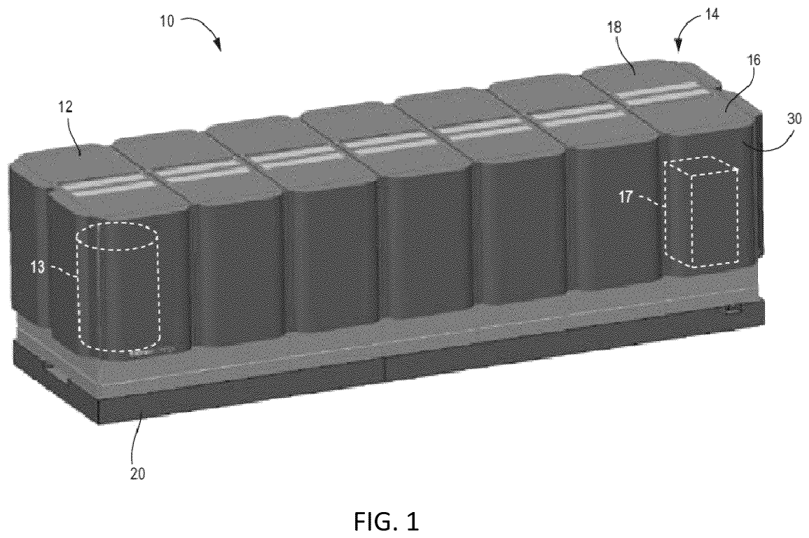

Referring to FIG. 1, a fuel cell power system 10 is shown according to an exemplary embodiment. The power system 10 may have a modular system layout. The power system 10 may contain modules and components described in U.S. Pat. Nos. 9,190,693, 9,755,263, 10,797,327 and 11,862,832, all of which are incorporated herein by reference in their entireties. A modular design of the power system 10 may provide flexible system installation and operation. Modules allow scaling of installed generating capacity, reliable generation of power, flexibility of fuel processing, and flexibility of power output voltages and frequencies with a single design set. The modular design results in an “always on” unit with very high availability and reliability. This design also provides an easy means of scale up and meets specific requirements of customer installations. The modular design also allows the use of available fuels and required voltages and frequencies which may vary by customer and/or by geographic region. In other embodiments, the power system 10 may include a unitary system layout (also referred to as a “classic” system layout) rather than a modular system layout.

The power system 10 shown in FIG. 1 includes a housing 14 in which at least one (preferably more than one or plurality) of power modules 12, one or more fuel processing modules 16, and one or more power conditioning (i.e., electrical output) modules 18 are disposed. In embodiments, the power conditioning modules 18 are configured to deliver direct current (DC). In alternative embodiments, the power conditioning modules 18 are configured to deliver alternating current (AC). In these embodiments, the power conditioning modules 18 include a mechanism to convert DC to AC, such as an inverter. For example, the system 10 may include any desired number of modules, such as 2-30 power modules, for example 3-12 power modules, such as 6-12 modules.

The power system 10 of FIG. 1 includes twelve power modules 12 (two rows of six modules stacked side to side), one fuel processing module 16, and one power conditioning module 18 on a pad 20. In some embodiments, the pad 20 may include a base that is formed of a concrete or similar structural material that may be configured for permanent installation of the power system 10 at a site. In other embodiments described in further detail below, the power modules 12, fuel processing module 16 and power conditioning module 18 may be disposed on a skid having an upper surface (i.e., a deck) which rests upon pedestals (e.g., metal rails) that are connected to the deck. The skid may be configured to enable quick deployments and/or temporary deployments of the power system 10 and may reduce installation costs and cycle times.

The housing 14 may include a cabinet to house each module 12, 16, 18. The terms cabinet, enclosure, and housing are used interchangeably herein. Alternatively, as will be described in more detail below, modules 16 and 18 may be disposed in a single cabinet. While two rows of power modules 12 are shown in FIG. 1, the system may comprise more than two rows of modules 12 or it may comprise a single row of modules 12.

Each power module 12 is configured to house one or more hot boxes 13. Each hot box contains one or more stacks or columns of fuel cells (not shown for clarity), such as one or more stacks or columns of solid oxide fuel cells having a ceramic oxide electrolyte separated by conductive interconnect plates. Other fuel cell types, such as PEM, molten carbonate, phosphoric acid, etc. may also be used.

The fuel cell stacks may comprise externally and/or internally manifolded stacks. For example, the stacks may be internally manifolded for fuel and air with fuel and air risers extending through openings in the fuel cell layers and/or in the interconnect plates between the fuel cells as disclosed in U.S. Patent Application Ser. No. 63/598,678, filed on Nov. 14, 2023, entitled “Internally Manifolded Interconnects with Plural Flow Directions and Electrochemical Cell Column Including Same,” which is incorporated herein by reference in its entirety.

Alternatively, the fuel cell stacks may be internally manifolded for fuel and externally manifolded for air, where only the fuel inlet and exhaust risers extend through openings in the fuel cell layers and/or in the interconnect plates between the fuel cells, as described in U.S. Pat. No. 7,713,649, which is incorporated herein by reference in its entirety. The fuel cells may have a cross flow (where air and fuel flow roughly perpendicular to each other on opposite sides of the electrolyte in each fuel cell), counter flow parallel (where air and fuel flow roughly parallel to each other but in opposite directions on opposite sides of the electrolyte in each fuel cell) or co-flow parallel (where air and fuel flow roughly parallel to each other in the same direction on opposite sides of the electrolyte in each fuel cell) configuration.

The power system 10 also contains at least one fuel processing module 16. The fuel processing module 16 includes components for pre-processing of fuel, such as adsorption beds (e.g., desulfurizer and/or other impurity adsorption) beds. The fuel processing module 16 may be designed to process a particular type of fuel. For example, the system may include a diesel fuel processing module, a natural gas fuel processing module, and an ethanol fuel processing module, which may be provided in the same or in separate cabinets. A different bed composition tailored for a particular fuel may be provided in each module. The processing module(s) 16 may process at least one of the following fuels selected from natural gas provided from a pipeline, compressed natural gas, methane, propane, liquid petroleum gas, gasoline, diesel, home heating oil, kerosene, JP-5, JP-8, aviation fuel, hydrogen, ammonia, ethanol, methanol, syn-gas, bio-gas, bio-diesel and other suitable hydrocarbon or hydrogen containing fuels. If desired, the fuel processing module 16 may include a reformer 17. Alternatively, if it is desirable to thermally integrate the reformer 17 with the fuel cell stack(s), then a separate reformer 17 may be located in each hot box 13 in a respective power module 12. Furthermore, if internally reforming fuel cells are used, then an external reformer 17 may be omitted entirely.

The power conditioning module 18 includes components for converting the fuel cell stack generated DC power to AC power (e.g., DC/DC and DC/AC converters described in U.S. Pat. No. 7,705,490, incorporated herein by reference in its entirety), electrical connectors for AC power output to the grid, circuits for managing electrical transients, and a system controller (e.g., a computer or dedicated control logic device or circuit). The power conditioning module 18 may be designed to convert DC power from the fuel cell power modules to different AC voltages and frequencies. Designs for 208V, 60 Hz; 480V, 60 Hz; 415V, 50 Hz and other common voltages and frequencies may be provided.

The fuel processing module 16 and the power conditioning module 18 may be housed in one cabinet of the housing 14. If a single input/output cabinet is provided, then modules 16 and 18 may be located vertically (e.g., power conditioning module 18 components above the fuel processing module 16 desulfurizer canisters/beds) or side by side in the cabinet.

As shown in one exemplary embodiment in FIG. 1, two rows of six power modules 12 are arranged linearly side to side with one row having the fuel processing module 16 and the other row having the power conditioning module 18. The rows of modules may be positioned, for example, adjacent to a building for which the system provides power.

The linear array of power modules 12 is readily scaled. For example, more or fewer power modules 12 may be provided depending on the power needs of the building or other facility serviced by the power system 10. The power modules 12 and input/output modules 16/18 may also be provided in other ratios. For example, in other exemplary embodiments, more or fewer power modules 12 may be provided adjacent to the input/output module 16/18. Further, the support functions could be served by more than one input/output module 16/18 (e.g., with a separate fuel processing module 16 and power conditioning module 18 cabinets). Additionally, while in the preferred embodiment, the input/output module 16/18 is at the end of the row of power modules 12, it could also be located in the center of a row power modules 12.

The power system 10 may be configured in a way to ease servicing of the components of the power system 10. All of the routinely or high serviced components (such as the consumable components) may be placed in a single module to reduce the amount of time required for the service person. For example, a purge gas (optional) and desulfurizer material for a natural gas fueled system may be placed in a single module (e.g., a fuel processing module 16 or a combined input/output module 16/18 cabinet). This would be the only module cabinet accessed during routine maintenance. Thus, each module 12, 16, and 18 may be serviced, repaired or removed from the system without opening the other module cabinets and without servicing, repairing or removing the other modules.

For example, as described above, the power system 10 can include multiple power modules 12. When at least one power module 12 is taken off line (i.e., no power is generated by the stacks in the hot box 13 in the off line module 12), the remaining power modules 12, the fuel processing module 16 and the power conditioning module 18 (or the combined input/output module 16/18) are not taken off line. Furthermore, the power system 10 may contain more than one of each type of module 12, 16, or 18. When at least one module of a particular type is taken off line, the remaining modules of the same type are not taken off line.

Thus, in a system comprising a plurality of modules, each of the modules 12, 16, or 18 may be electrically disconnected, removed from the power system 10 and/or serviced or repaired without stopping an operation of the other modules in the system, allowing the fuel cell system to continue to generate electricity. The entire power system 10 does not have to be shut down if one stack of fuel cells in one hot box 13 malfunctions or is taken off line for servicing.

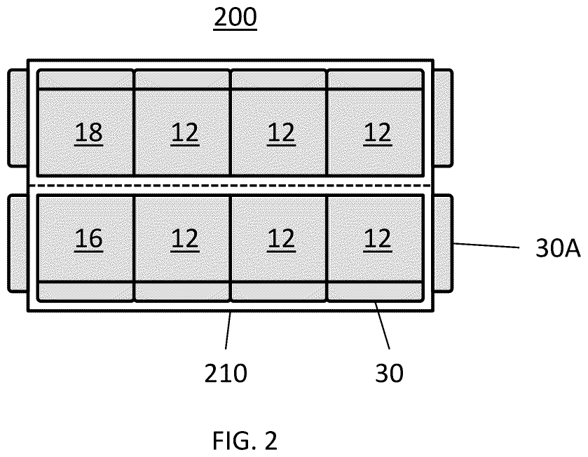

FIG. 2 illustrates top plan view of a fuel cell power system 200 according to various embodiments of the present disclosure. The power system 200 is similar to the power system 10 of FIG. 1. As such, similar reference numbers are used for similar elements, and only the differences therebetween will be described in detail.

Referring to FIG. 2, the power system 200 includes power modules 12, a power conditioning module 18, and a fuel processing module 16 disposed on a pad 210. The system 200 may include doors 30 to access the modules 12, 16, 18. The power system 200 may further include cosmetic doors and/or panels 30A.

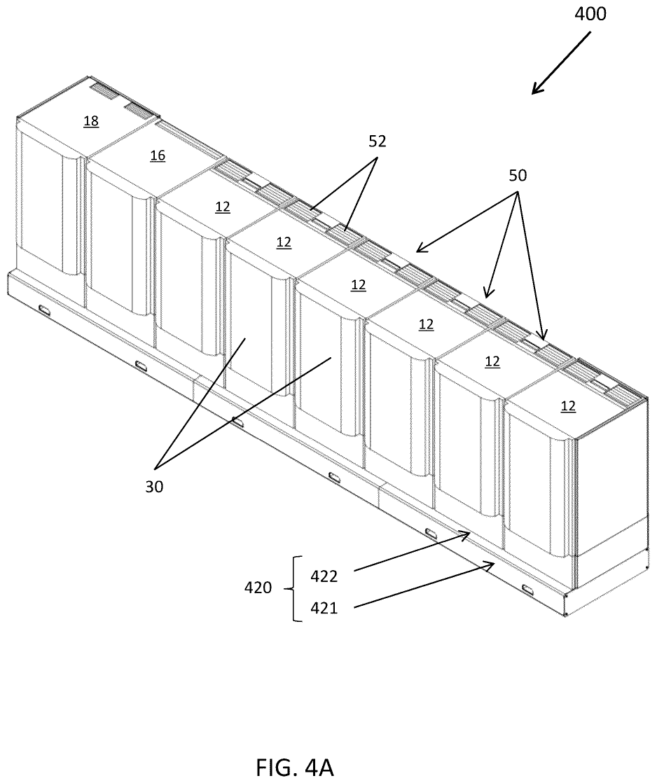

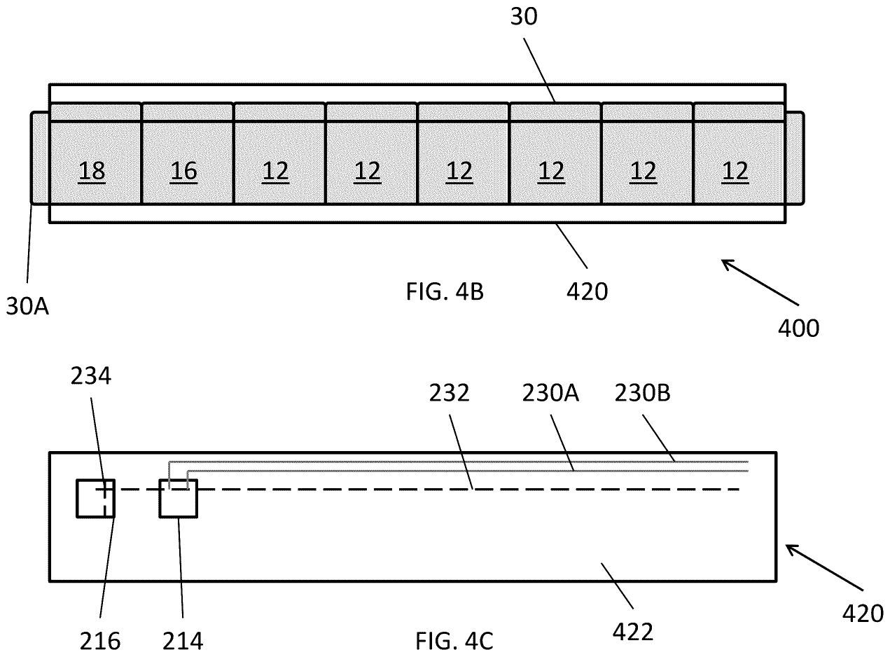

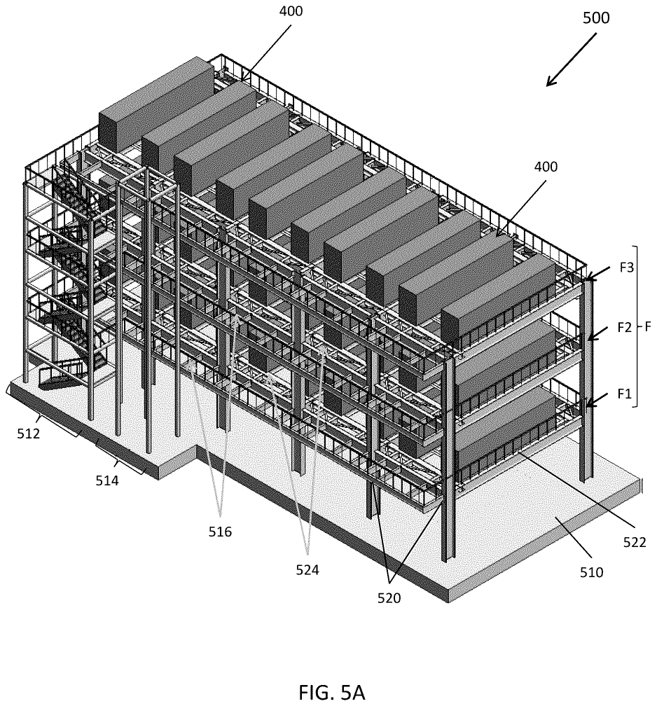

The power modules 12 may be disposed in a back-to-back configuration. In particular, the power modules 12 may be disposed in parallel rows, and the fuel processing module 16 and the power conditioning module may be disposed at ends of the rows. Accordingly, the system 200 has an overall rectangular configuration, and may be shorter in length than other systems, such as the system 400 of FIG. 4A. As such, the power system 200 can be disposed in locations where space length is an issue. For example, the system 200 may fit in a parking spot adjacent to a building to which power is to be provided.

While the system 200 is shown to include two rows of three power modules 12, the present disclosure is not limited to any particular number of power modules 12. For example, the system 200 may include 2-30 power modules 12, 4-12 power modules 12, or 6-12 power modules 12, in some embodiments. In other words, the power system 200 may include any desired number of power modules 12, with the power modules 12 being disposed in a back-to-back configuration. In addition, the positions of the fuel processing module 16 and the power conditioning module 18 may be reversed, and/or the modules 16, 18 may be disposed on either end of the system 200.

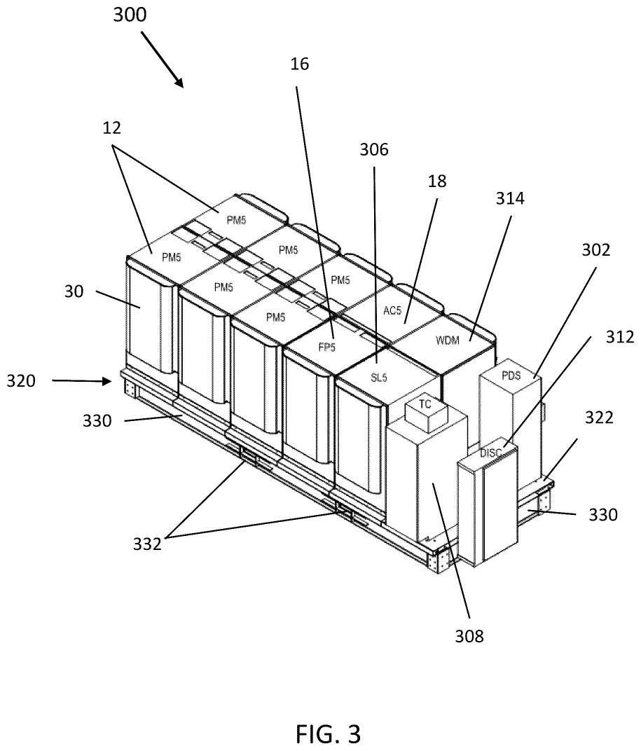

FIG. 3 is a perspective view showing an electrochemical cell system 300, such as a fuel cell power system 300, including a plurality of modules located on a skid 320. The power system 300 may include one or more power modules 12 (labeled PM5 in FIG. 3), one or more fuel processing modules 16 (labeled FP5 in FIG. 3) and one or more power conditioning modules 18 (labeled AC5 in FIG. 3), which may be disposed on the same skid 320. The system 300 may further include doors 30 to access the modules 12, 16, 18. Alternatively, the system 300 may comprise an electrolyzer cell system containing electrolyzer modules, water distribution module and power module located on the same skid.

When electrochemical cell system 300 is configured as a fuel cell power system, power modules 12 may be disposed in a back-to-back configuration. In particular, the power modules 12 may be disposed in parallel rows. A fuel processing module 16 and a power conditioning module 18 may be disposed in a back-to-back configuration at the ends of the respective rows of power modules 12.

The system 300 may also include additional ancillary equipment. The ancillary equipment may include one or more additional modules, such as a water distribution module (WDM) 314. The WDM 314 may include water treatment components (e.g., water deionizers) and water distribution pipes and valves which may be connected to a water supply (e.g., a municipal water supply pipe), and to the individual modules in the system 300. The ancillary equipment of the system 300 may also include a step load module 306 (labeled SL5 In FIG. 3). The step load module 306 may include storage components, such as batteries and/or ultracapacitors (also known as supercapacitors), which may support the power system in meeting step load changes. The WDM 314 and the step load module 306 may be disposed in a back-to-back configuration adjacent to the power conditioning module 18 and the fuel processing module 16, respectively.

In some embodiments, the ancillary equipment of the system 300 may additionally include a telemetry cabinet 308 (labeled TC in FIG. 3) that may include system controllers and communication equipment that enables the system 300 to communicate with a central controller and/or system operators. In some embodiments, the ancillary equipment of the system 300 may also include a power distribution system 302 (labeled PDS in FIG. 3) that may control power distribution to various components located on and/or off of the skid 320. In some embodiments, the ancillary equipment of the system 300 may also include a disconnect system 312 (labeled DISC in FIG. 3), such as disconnect switchgear, which may be configured to protect, isolate and de-energize components of the system 300 in the event of a fault condition and/or for maintenance purposes. In some embodiments, the disconnect system 312 may be combined with or substituted with a backup power supply (BPS). A disconnect/BPS system on-board the skid 320 may allow for quick and easier installation as a disconnect/BPS does not have to be set during construction.

In some embodiments, power distribution, telemetry and disconnect/BPS functions may be combined in a single unit (e.g., an electrical distribution system (“EDS”) unit) that may be located on or attached to the skid 320. In some embodiments, the EDS unit may include a single cabinet or housing disposed on the skid 320. This may allow for further skid footprint reduction and may provide for a quicker and cheaper installation because the equipment for power distribution, telemetry and disconnect/BPS functionality does not need to be set separately during construction.

The skid 320 may have a generally rectangular shape. However, other horizontal shapes may also be used. In some embodiments, the skid 320 may have a length dimension that is at least about 8 feet, such as between 8 and 40 feet, including between 20 and 25 feet. The skid 320 may have a width dimension that is at least about 4 feet, such as between 4 and 15 feet, including between 7 and 10 feet. The skid 320 may include an upper surface, which may also be referred to as a deck 322, on which the power modules 12, fuel processing module 16, power conditioning module 18, and optional ancillary equipment (e.g., step load module 306, water distribution module (WDM) 314, telemetry cabinet 308, power distribution system 302, disconnect system/BPS 312, etc.) may be supported.

While the system 300 is shown to include two rows of three power modules 12 on a skid 320, the present disclosure is not limited to any particular number of power modules 12 on the skid 320. In some embodiments, the power modules 12 may be disposed as a pair of rows of power modules 12 in a back-to-back configuration on the skid 320. Alternatively, a single row of power modules 12, or more than two rows of power modules 12, may be located on the skid 320. In addition, the positions of the fuel processing module 16 and the power conditioning module 18 on the skid 320 may be reversed, and/or the modules 16, 18 may be disposed on either end of the skid 320. Further, in various embodiments, some or all of the auxiliary equipment 314, 306, 308, 302, and 312 may either be omitted from the system 300 or located off the skid 320.

Further embodiments include electrolyzer cell systems disposed on a skid 320. An electrolyzer cell system may be used for hydrogen generation. One or more electrolyzer modules, which may be similar to the power modules 12 shown in FIG. 3, may be disposed on the deck 322 of a skid 320. Each electrolyzer module may include a housing or cabinet that is configured to house one or more hot boxes 13 (see FIG. 1). Each hot box 13 of an electrolyzer module may contain at least one electrolyzer cell stack including multiple electrolyzer cells, such as solid oxide electrolyzer cells (SOECs). Each electrolyzer module may contain additional components, such as a steam recuperator, a steam heater, an air recuperator, an air heater and/or a stack heater that may be located inside or outside of a hot box 13. During operation, the at least one electrolyzer cell stack may be provided with steam and electric current or voltage from an external power source. In particular, the steam may be provided to the fuel electrodes of the electrolyzer cells of the stack, and the power source may apply a voltage between the fuel electrodes and the air electrodes of the electrolyzer cells, in order to electrochemically split water molecules and generate hydrogen (e.g., H₂) and oxygen (e.g., O₂). Air may also be provided to the air electrodes, in order to sweep the oxygen from the air electrodes. As such, the stack may output a hydrogen stream and an oxygen-rich exhaust stream. The hydrogen stream may be used as a hydrogen fuel source and/or provided to a hydrogen storage system for later use. Additional supporting equipment for the electrolyzer module(s) may be located on the skid 320. In some embodiments, a combined fuel cell power and electrolyzer hydrogen generation system (i.e., the PES system) may include at least one power module and at least one electrolyzer module disposed on a skid 320 for co-generation of electric power and hydrogen. The electrolyzer cell system may contain components as disclosed in U.S. Patent Application Publication Nos. 2023/0399762 and 2022/0372636, both of which are incorporated herein by reference in their entireties.

Referring again to FIG. 3, the deck 322 of the skid 320 may be supported above the ground by a plurality of support rails 330 that are connected to the deck 322. The support rails 330 may include metal (e.g., steel) rails, such as I-beams, which may be connected together (e.g., via mechanical fasteners, such as bolts, and/or welded together) to provide a suitably strong support base. The support rails 330 may extend around the periphery of the skid 320. Additional support rails 330 (not visible in FIG. 3) may extend across the skid beneath the deck 322. At least some of the support rails 330 may include fork pockets 332 for the insertion of the prongs of a forklift for transport, installation and/or removal of the system 300. The skid 320 may additionally include lift points for a crane, such as lift hooks.

FIG. 4A illustrates a perspective view of a linear electrochemical system 400, such as a fuel cell power system or an electrolyzer cell system according to various embodiments of the present disclosure. FIG. 4B illustrates top plan view of the electrochemical cell system 400. FIG. 4C illustrates a schematic view of a skid 420 of FIG. 4A. The electrochemical cell system 400 includes similar components to the electrochemical cell system 10 of FIG. 1. As such, similar reference numbers are used for similar elements, and only the differences therebetween will be described in detail.

Referring to FIGS. 4A-4C, the electrochemical cell system 400 includes power modules 12, a power conditioning module 18, and a fuel processing module 16 disposed on a skid 420. The system 400 may include doors 30 to access the modules 12, 16, 18.

The power modules 12 may be disposed in a linear configuration. In particular, the power modules 12 may be disposed in one row, and the fuel processing module 16 and the power conditioning module 18 may be disposed at an end of the row. In an alternative embodiment, the fuel processing module 16 and the power conditioning module 18 may be disposed in the middle of the row. Accordingly, the electrochemical cell system 400 has an overall linear configuration, and may be fit into locations having linear space, but limited width.

While the electrochemical cell system 400 is shown to include a row of six power modules 12, the present disclosure is not limited to any particular number of power modules 12. For example, the system 400 may include 2-30 power modules 12, 4-12 power modules 12, or 6-12 power modules 12, in some embodiments.

Each power module 12 may include a ventilation unit 50 disposed on the back side of the power module 12 cabinet, opposite the door 30. The ventilation units 50 may be configured to output module exhaust vertically through cover vents 52. The module exhaust may include stack exhaust generated by module stacks and cabinet air exhausted from the module cabinet. The ventilation units 50 may include a fan (not shown) to facilitate the output of the module exhaust.

The skid 420 includes a skid rails 421 and a deck 422, as shown in FIG. 4A. The deck 422 may include first and second through holes 214, 216. The rails 421 and the deck 422 may be formed of steel or another metal.

The skid 420 may also include plumbing (for example, water pipe 230A and fuel pipe 230B), wiring 232, and a system bus bar 234 located below the deck 422 and exposed in the holes 214, 216. In particular, the wiring 232 may be connected to one or more of the modules. For example, the wiring 232 may be connected to the bus bar 234 and each of the power modules 12. The bus bar 234 may be connected to the power conditioning module 18. The power conditioning module 18 may be connected to an external load through the second through hole 216. The bus bar 234 may be disposed on an edge of the second through hole 216, such that the wiring 232 does not extend across the second through hole 216. However, the bus bar 234 may be disposed on an opposing side of the second through hole 216, such that the wiring 232 does extend across the second through hole 216, if such a location is needed to satisfy system requirements.

According to some embodiments, the plumbing 230A/230B and the wiring 232 may be located adjacent to the doors 30, in order to facilitate connecting the same to the modules 12, 16, 18. In other words, the plumbing 230A/230B and the wiring 232 may be located adjacent to an edge of the deck 422. In some embodiments, the wiring 232 may be in the form of cables, and the bus bar 234 may be omitted.

Electrochemical cell (e.g., fuel cell and electrolyzer cell) systems may have relatively large space requirements, especially when multiple electrochemical cell systems are utilized at the same site to generate power or to electrolyze water to generate hydrogen. For example, in order to provide a high power output with a relatively small area site, fuel cell power systems are placed on multiple levels of a structure to increase site power density. Embodiments of the present disclosure provide multilevel structures which provide a reduced construction cost and duration, and a smaller exhaust duct footprint.

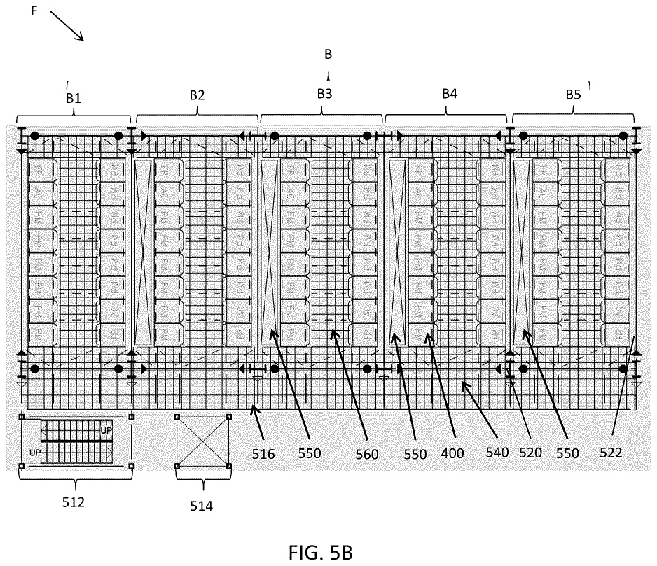

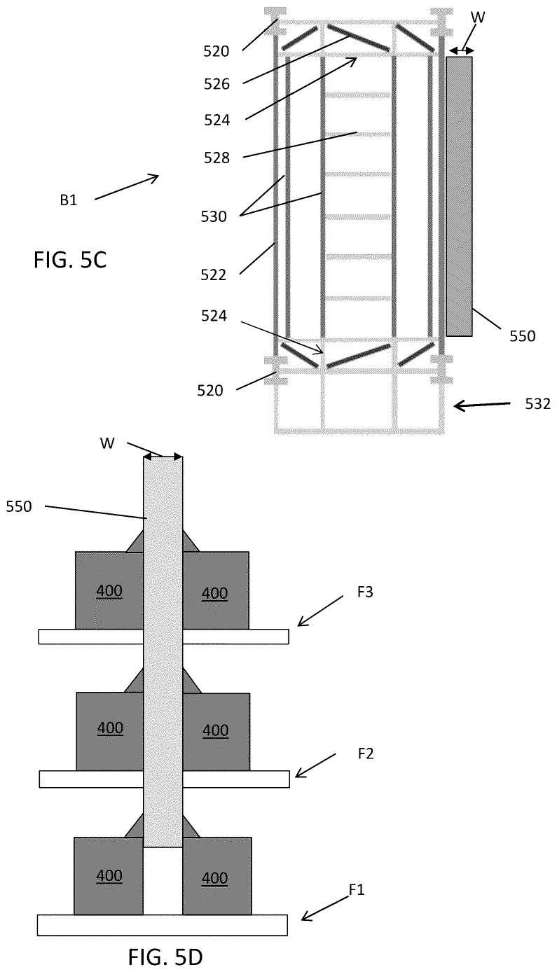

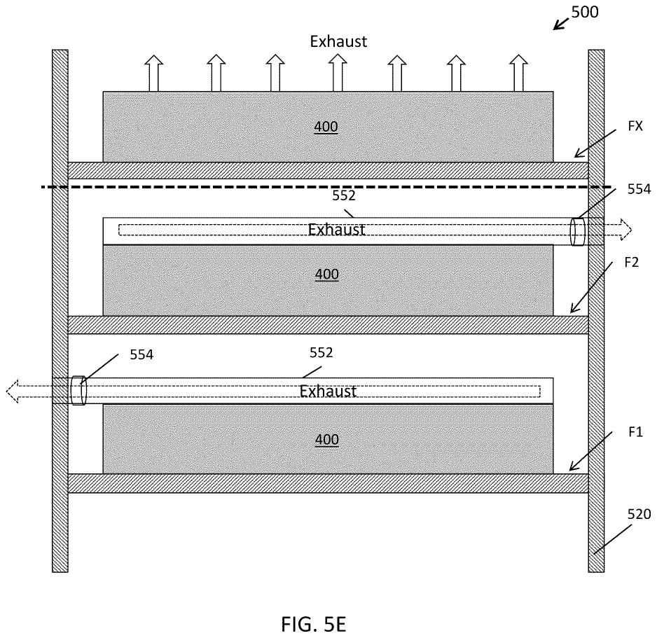

FIG. 5A is a perspective view of a multilevel electrochemical cell system 500 comprising vertically integrated electrochemical cell (e.g., fuel cell or electrolyzer cell) systems 400, according to various embodiments of the present disclosure, FIG. 5B is a schematic top view showing one floor F of the multilevel electrochemical cell system 500 of FIG. 5A, FIG. 5C is a schematic top view showing structural elements of a bay B1 of the floor F of FIG. 5B, FIG. 5D is a schematic side view showing an exhaust conduit 550 of the multilevel electrochemical cell system 500 of FIG. 5A, and FIG. 5E is a schematic side cross-sectional view of the multilevel electrochemical cell system 500 including an alternate exhaust duct configuration, according to various embodiments of the present disclosure.

Referring to FIGS. 5A-5D, the multilevel electrochemical cell system 500 may include a base 510 (e.g., a ground floor) and one or more floors F located above the base 510 that are each configured to support multiple electrochemical cell systems 400. For example, the multilevel electrochemical cell system 500 may include the base (e.g., the ground floor) 510, a first floor F1, a second floor F2, and a third floor F3, as shown in FIG. 5A. However, the multilevel electrochemical cell system 500 is not limited to any particular number of floors F. For example, the number of floors F may be selected based on a structure design for a particular site. The electrochemical cell systems 400 may be located on the floors F, and optionally on the base 510. Alternatively, no electrochemical cell systems 400 may be located on the base 510.

In some embodiments, the multilevel electrochemical cell system 500 may also include columns 520, stairs 512, a material lift 514, and/or exhaust manifolds 550 (see FIGS. 5B, 5C, 5D). In some embodiments, the floors F may include external cantilevered catwalks 516 that are connected to the stairs 512. The components of the multilevel electrochemical cell system 500, other than the electrochemical cell systems 400 and the base 510, may primarily comprise a metal, such as steel, in order to minimize the use of concrete. For example, each of the floors F may comprise a metal grate (e.g., a steel grate) or solid metal (e.g., steel) plate. The base 510 may comprise concrete or metal. For example, the base 510 may comprise a concrete pad located on the ground outside of a building or a floor of a building. It is believed that a reduction in the use of concrete reduces greenhouse gas emissions. In some embodiments, various components of the multilevel electrochemical cell system 500 may be prefabricated to reduce costs. For example, the columns 520, the floors F, the stairs 512 and/or the material lift 514 may be prefabricated or partially prefabricated structures, which are delivered to the system 500 site. The base 510 may also comprise a prefabricated concrete base or base portions for outdoor installation or a pre-existing floor of a building. Alternatively, the base 510 may comprise a poured concrete base which is formed on site.

The columns 520 may be anchored to the base 510 and may extend in a vertical direction. In some embodiments the columns 520 may be steel I-beams or steel tubes, which may be internally reinforced with concrete. The floors F may be attached to the columns 520, such that the columns 520 vertically support the floors F. The columns 520 may include connection elements, such as brackets, configured to facilitate connection with the floors F.

As shown in FIG. 5B, each floor F may be divided into a number of bays B, such as bays B1-B5. Each bay B may include two electrochemical cell systems 400 separated by a servicing aisle 560. However, other electrochemical cell systems, such as systems 10, 200 or 300 may be located in structure 500 instead of or in addition to the systems 400.

Referring to FIGS. 5A, 5B and 5C, each floor F may include horizontal metal structural support elements, such as floor beams 522. In one embodiment, vertical columns 520 and the horizontal floor beams 522 may be rigidly connected to form a moment frame. For example, in a moment frame, the floor beams 522 may be connected to the columns 520 using shear connection angles and bolts such that moments are transferred through the connections. In another embodiment, the vertical columns 520 and the horizontal floor beams 522 may be connected by pins or other connectors to form a braced frame in which the connections do not transfer moments.

In some embodiments, the floors F may include other structural components, such as support frames 524, frame bracing 526, aisle bracing 528, skid rails 530, catwalk framing 532, and/or flooring 540. The floor beams 522 and support frames 524 may be connected to the columns 520. In one embodiment, the floor beams 522 and/or the support frames 524 are attached to the columns 520 without welding. For example, the floor beams 522 and/or the support fames 524 may be attached to the columns 520 using bolts, pins, clamps, and/or other suitable fasteners.

The support frames 524 may be ladder-like structures. The support frames 524 may be prefabricated or partially prefabricated to reduce costs. For example, the support frames 524 may be constructed of riveted or welded steel components. In some embodiments, the support frames 524 may include frame bracing (e.g., diaphragm bracing) 526 to provide additional structural rigidity.

As shown in FIG. 5C, the skid rails 530 may be attached to the support frames 524 and may extend parallel to the floor beams 522. The skid rails 530 may comprise rails of a skid 420, such as the rails 421 described above with respect to FIGS. 4A-4C. The skid deck 422 (not shown in FIG. 5C) may optionally be placed on the skid rails 530. Alternatively, the skid deck 422 may be omitted if the bottom surface of the electrochemical cell system 400 forms the skid deck. In some embodiments, two pairs of skid rails 530 may be located between each pair of floor beams 522 in each bay B. In other words, each bay B may include two pairs of skid rails 530. Each pair of skid rails 530 may be configured to receive and support one electrochemical cell system 400.

The aisle bracing 528 may connect adjacent skid rails 530 of each bay B. The catwalk bracing 532 may be connected to one of the support frames 524 and may extend outside of the columns 520. Flooring 540 may be supported by the support frames 524, the aisle bracing 528, and the catwalk bracing 532. As such, flooring 540 may be present in the aisles 560 and the catwalk 516. In some embodiments, the flooring 540 may comprise an open metal grate to reduce costs and increase air flow between levels L. Alternatively, the flooring 540 may comprise a solid metal plate.

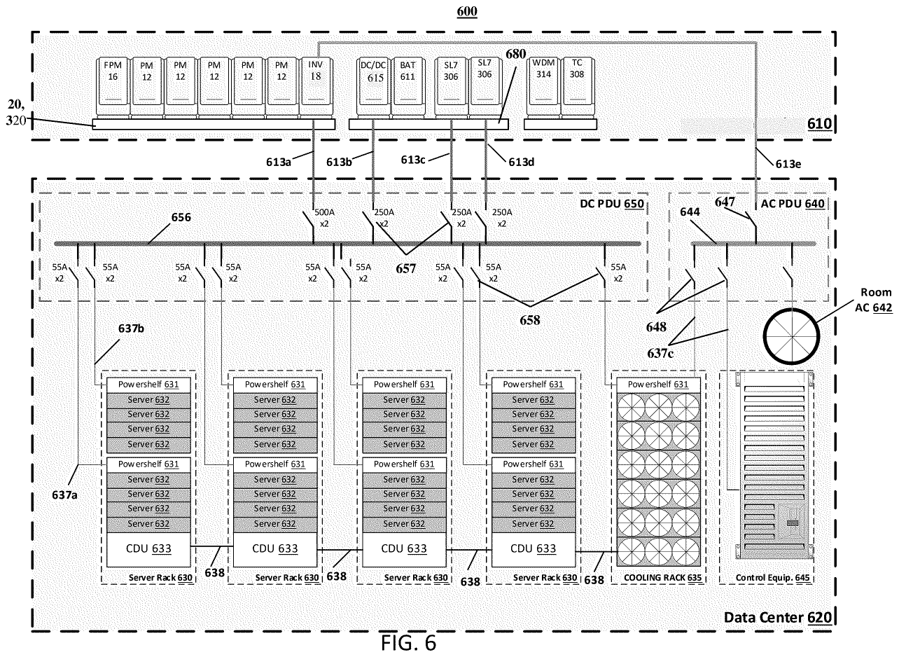

In the embodiment of FIGS. 5A-5E, the floor beams 522 comprise a plurality of vertically separated floor beams. A plurality of vertically separated floors F are attached to the columns 520 and the floor beams 522. Each of the plurality of floors F comprise respective skid rails 530, and the electrochemical cell systems 10, 200, 300 or 400 are located on the plurality of floors F. Similar configurations are contemplated for the combined electrochemical power generation and data center systems of FIGS. 6-8.

The exhaust ducts 550 may receive exhaust from adjacent pairs of the electrochemical cell systems 400 located in adjacent bays B. In particular, each exhaust duct 550 may receive exhaust from the electrochemical cell systems 400 located in adjacent bays B. The exhaust ducts 550 may extend through the second and third floors F2, F3 and exit the top of the multilevel electrochemical cell system 500. The outermost modules in electrochemical cell systems 400 in bays B1 and B5 (e.g., six power modules in bay B1 and six power modules in bay B5), which are adjacent to opposing sides of the multilevel electrochemical cell system 500, may not be connected to an exhaust duct 550, and these electrochemical cell systems 400 may output their exhaust through the open opposing sides of the multilevel electrochemical cell system 500. As such, an exhaust duct 550 may be omitted from bay B1. In some embodiments, the electrochemical cell systems 400 on the upper most floor F of the multilevel electrochemical cell system 500 (e.g., the third floor F3) may optionally output exhaust directly to the atmosphere, without being connected to the exhaust ducts 550.

A three or four floor multilevel electrochemical cell system 500 may include exhaust ducts 550 having a width W that ranges from about 2.5 ft. to about 3.5 ft., such as about 3 ft. A five floor multilevel electrochemical cell system may include exhaust ducts 550 having a width W that ranges from about 3 ft. to about 4 ft., such as about 3.5 ft. A six or seven floor multilevel electrochemical cell system may include exhaust ducts 550 having a width W that ranges from about 3.5 ft. to about 4.5 ft., such as about 4 ft.

Referring to FIG. 5E, the multilevel electrochemical cell system 500 may include horizontal exhaust ducts 552 attached to the electrochemical cell systems 400. The exhaust ducts 552 may be configured to laterally direct exhaust from the electrochemical cell systems 400, such that the exhaust may be expelled from one or more of the open sides of the multilevel electrochemical cell system 500.

Exhaust fans 554 may optionally be included in the horizontal exhaust ducts 552 to move the exhaust through the corresponding exhaust ducts 552 and/or out of the multilevel electrochemical cell system 500. In various embodiments, the electrochemical cell systems 400 disposed on the top floor of the multilevel electrochemical cell system 500 may be either connected to an exhaust duct 550, or may be unconnected to an exhaust duct and may output the exhaust directly into the atmosphere.

The horizontal exhaust system of FIG. 5E may be particularly suitable for multilevel electrochemical cell systems 500 having a high number of floors, such as four or more floors. In particular, the horizontal exhaust system may obviate the need for wider vertical exhaust ducts.

Referring to FIGS. 5A-5E, in various embodiments, the multilevel electrochemical cell system 500 may be constructed in a floor-by-floor method. In particular, the columns 520 may be anchored to the base 510. The first floor F1 may be assembled and attached to the columns 520. In one embodiment, the first floor F1 may be pre-assembled prior to being attached to the columns 520. Alternatively, the floor beams 522 may be attached to the columns 520 to form a moment frame (520, 522). The remaining structural components of the floors F (e.g., support frames 524, frame bracing 526, aisle bracing 528, catwalk framing 532, flooring 540 and optionally the skid rails 530) may then be placed into the frame (520, 522) and secured in place in the frame. Electrochemical cell systems 400 may then be installed onto the first floor F1 using, for example, a crane that is used to assemble the first floor F1. The second floor F2 may then be assembled. Electrochemical cell systems 400 may then be installed on the second floor F2. The process may be repeated for each floor of the system 500.

In an alternative embodiment, the electrochemical cell systems 400 may be installed after all the floors F of the multilevel electrochemical cell system 500 are constructed. For example, the material lift 514 may be used to raise materials to the corresponding floor F. Each module of the electrochemical cell system 400 may be lifted by the material lift 514 (if it has sufficient size) or a crane to the corresponding floor F, and then be moved into position using, for example, skates and/or lift jacks.

The embodiments of the present disclosure are generally directed to vertically integrated fuel cell systems and data center servers. Servers for data centers are typically arranged in racks in enclosures that require power and cooling. An embodiment of the present disclosure integrates a fuel cell system and a data center in the same vertical structure. Integration of the data center and fuel cell system in the same vertical structure permits the use of shorter power buses (i.e., power cables) which reduces power losses and provides a more efficient power transfer. It also permits a direct DC power connection from the fuel cell system to the servers of the data center without converting the DC power generated by the fuel cell power modules to AC power and then back to DC power, which eliminates power losses due to the conversion. Furthermore, data centers which have frequently fluctuating power requirements, such as data centers used for artificial intelligence (AI) computation, generate undesirable harmonic fluctuations in the AC power frequency on the AC power bus. Since an AC power bus between the servers (i.e., sever racks) and the DC power generating fuel cell system is not used, the harmonic interference with the AC power supply is also eliminated in the system of this embodiment. Finally, step load modules containing supercapacitors (i.e., ultracapacitors) used together with the fuel cell system provide load following and smooth out the power demand spikes from the AI data center.

FIG. 6 illustrates a combined system 600 including a fuel cell power generation system 610 and an associated data center 620 containing server racks 630 powered by the fuel cell power generation system 610. The power generation system 610 may be co-located with the data center 620 in a multi-level structure, such as a building or an outdoor structure, as will be described in more detail below. With reference to FIGS. 1-6, the power generation system 610 may include a plurality of fuel cell power modules (PM) 12 that generate power from a fuel, as described above. The fuel may be processed by one or more fuel processing modules (FPM) 16. A FPM 16 and a power conditioning module (INV) 18 may be located on the same base (e.g., skid 320 or concrete pad 20) as the PMs 12.

The power generation system 610 may also include one or more battery modules 611 that include battery backup power supplies and one or more optional DC/DC converter modules 615 which include one or more DC/DC converters (e.g., buck, boost and/or buck-boost converters) which are configured to increase or decrease the DC power output from the battery modules 611. The power generation system 610 may also include one or more step load modules (SL7) 306 that include supercapacitors (i.e., ultracapacitors) that provide power to the data center 620 to fill in short gaps in data center 620 load power demand. The battery modules 611, the DC/DC converter module(s) 615 and the step load modules 306 may be located on the same step load module base (e.g., same skid) 680 or different bases from each other. In one embodiment, the battery modules 611, the DC/DC converter module(s) 615 and the step load modules 306 are located on a different step load base 680 than the PMs 12, the FPM 16 and the power conditioning module (INV) 18.

The power generation system 610 may also include a water distribution module (WDM) 314 and a telemetry cabinet (TC) 308 which may operate as described above. The telemetry cabinet 314 may include controllers and communications equipment for wired and/or wireless communications with the data center 620 and/or with the power generation system 610 central control facility. The WDM 314 and TC 308 may be located on a common base that is separate from the other module bases.

The power generation system 610 may generate DC (direct current) power in the fuel cell power modules 12 and provide the DC power to the respective power conditioning module 18 located on the same base (20, 320) as the respective power modules 12 via one or more DC buses which may extend through the common base (20, 320). The step load modules 306, the battery modules 611 and the DC/DC converter modules 615 may be located on the separate step load module base 680 from that of the power modules 12. The power conditioning module (INV) 18 is electrically connected to an AC power distribution unit (PDU) 640 via an AC line (e.g., AC bus or cable) 613e and to the DC PDU 650 via a DC line (e.g., DC bus or cable) 613a. Specifically, an input of the DC/AC inverter located in the power conditioning module 18 is electrically connected to the DC bus power output of the PMs 12, and the output of the inverter is electrically connected to the AC line 613e. In contrast, the DC line 613a is directly electrically connected to the DC bus power output of the PMs 12, such that the electrical connection does not pass through the inverter. Thus, the PMs 12 supply DC power directly to the DC PDU 650 via the DC line 613a without passing through the inverter.

The DC/DC converter module(s) 615 may be electrically connected to the DC PDU 650 via a second DC line 613b. DC line 613b provides power from the battery modules 611 to the DC PDU 650. The step load modules 306 may be electrically connected to the DC PDU 650 via one or more additional (e.g., third and fourth) DC lines 613c, 613d.

The AC PDU 640 includes an AC bus 644 and one or more AC switches 647, 648. The AC bus 644 receives AC power provided via the AC line 613e from the inverter of the power conditioning module 18. The AC bus 644 provides AC power via AC connection lines 637c to various AC powered auxiliary components of the data center 620, such as cooling devices and/or control equipment that are configured to run on AC power. The cooling devices include optional air conditioning unit(s) 642 (if the data center 620 is located inside a room of a building or inside an air conditioned structure, such as an air conditioned shipping container) and/or one or more AC power shelves 631 of AC powered cooling racks 635. The control equipment 645 may include AC powered control electronics that provide power control, load balancing, temperature control, ventilation and/or air conditioning control, and other building control and auxiliary functions. The AC switch 647 may be used to connect or disconnect the AC bus 644 to and from the AC line 613e. The AC switches 648 may be used to connect or disconnect the AC bus 644 to and from the AC connection lines 637c connected to the AC loads 631, 642, 645.

The DC PDU 650 includes a DC bus 656 and one or more DC switches 657, 658. The DC bus 656 receives DC power provided via the DC lines 613a-613d from the power conditioning module 18, the DC/DC converter module 615 and the step load modules 306. The DC bus 656 provides DC power to DC powered power shelves 631 of the DC server racks 630 which contain server shelves supporting the servers 632. The DC bus may optionally provide DC power to a DC powered power shelf 631 of the cooling rack 635 if the cooling rack 635 is a DC powered cooling rack rather than an AC powered cooling rack. The DC switches 657 may be used to connect or disconnect the DC bus 656 to and from the DC lines 613a-613d. The DC switches 658 may be used to connect or disconnect the DC bus 656 to and from the DC connection lines 637a, 637b connected to the DC power shelf 631 loads. In some embodiments, the power shelf 631 of the cooling rack 635 may be configured to accept AC or DC power and may have an internal inverter so that the cooling rack 635 may be powered by either the DC PDU or the AC PDU for redundancy.

DC/DC converters located in the PMs 12 or in the power conditioning module 18 may convert a first voltage or current generated by the fuel cell stacks or columns in the PMs 12 to a second voltage or current, and may supply the second voltage or current to the DC power shelves 631 of the data center 620 via the power conditioning module 18, the DC line 613a, the DC bus bar 656, switches 657 and 658 and the DC connection lines 637a, 637b. The battery modules 611 may supply DC power to the DC power shelves 631 (when the DC load exceeds the PM 12 DC power output) via the DC/DC converter module 615, the DC line 613b, the DC bus bar 656, switches 657 and 658 and the DC connection lines 637a, 637b. The step load modules 306 may be directly electrically connected to the DC bus bar 656 via DC lines 613c and 613d and the DC switches 657, and may be configured to supply DC power quickly to the DC PDU 650 in response to DC power shelf 631 load demand spikes. The DC bus bar 656 may be electrically connected via DC connecting lines 637a and 637b to the power shelves 631 that power one or more servers 632 located on server shelves of server racks 630 of the data center 620.

The servers 632 may comprise AI servers, such as AI graphics processing units, which are liquid cooled, such as by liquid heat exchange or by dielectric liquid immersion cooling. The cooling fluid may be provided to the server racks 630 from respective cooling distribution units 633. The cooling liquid flows through and/or adjacent to the servers 632 to collect heat from the servers. The cooling liquid may circulate between the cooling rack 635 and the CDU 633 of each server rack 630 via cooling lines 638. The CDUs 633 may supply the cooling liquid to various heat sinks of processors of the servers 632. The heated liquid may then return from the server racks 630 via the cooling lines 638 and is re-cooled in the heat exchanger(s) of the cooling rack 635. The heat exchanger(s) of the cooling rack 635 may comprise an air/liquid heat exchanger(s) in which the fluid in the cooling lines 638 is cooled by ambient air provided on the outer surface of the cooling lines by one or more fans. However, other heat exchanger types may also be used.

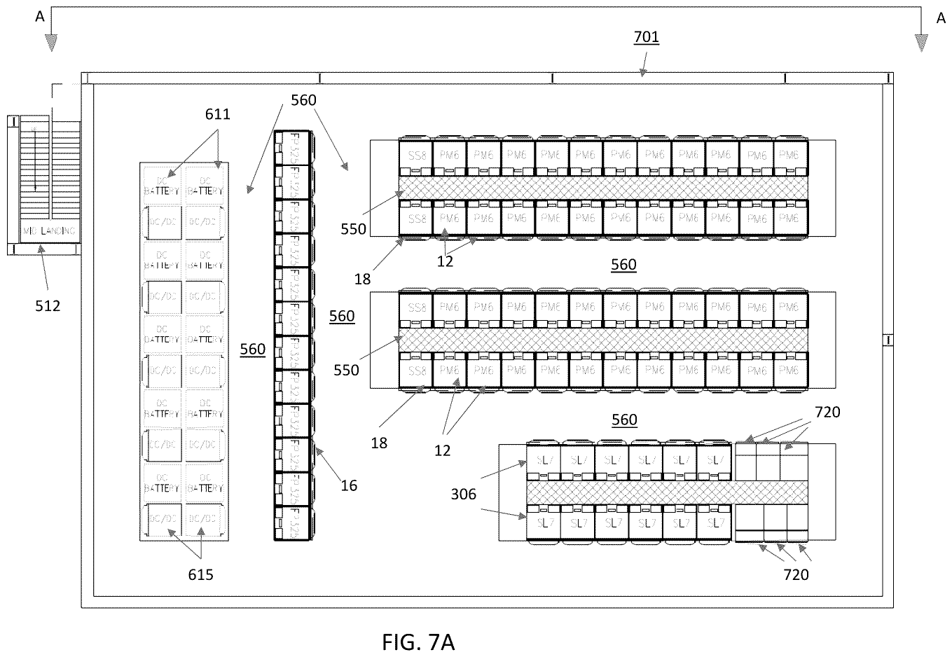

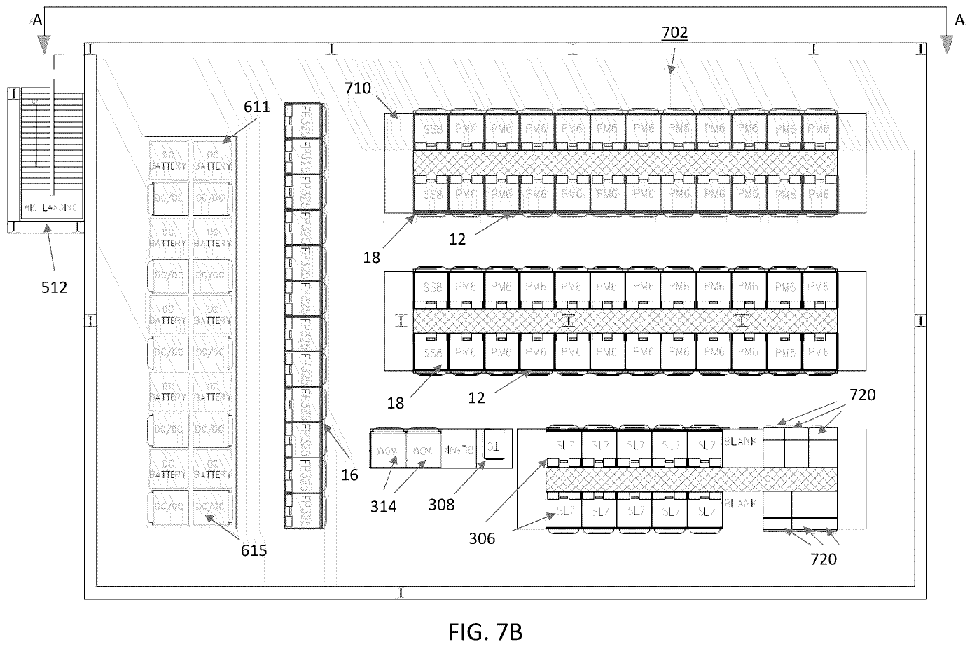

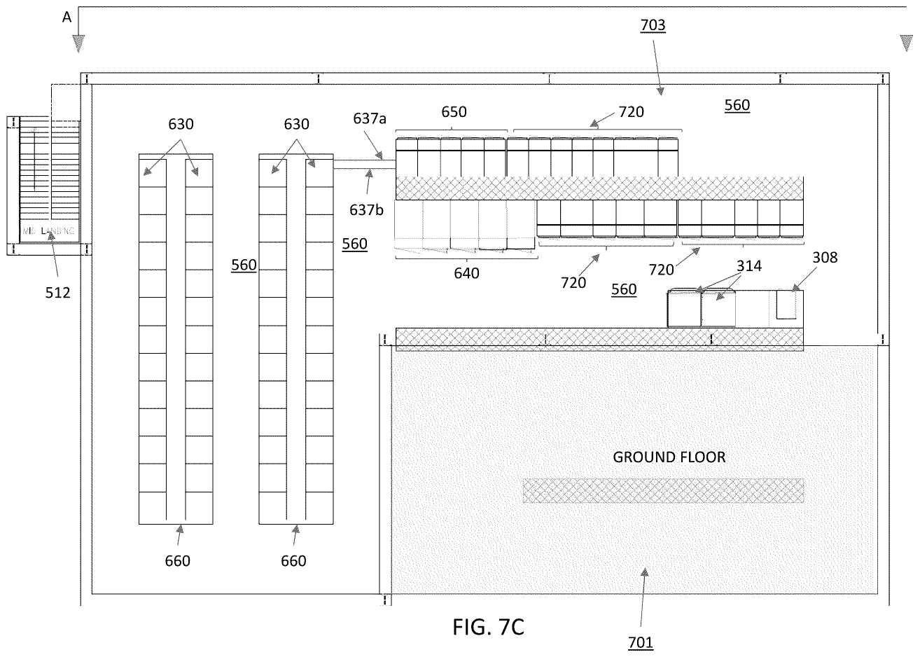

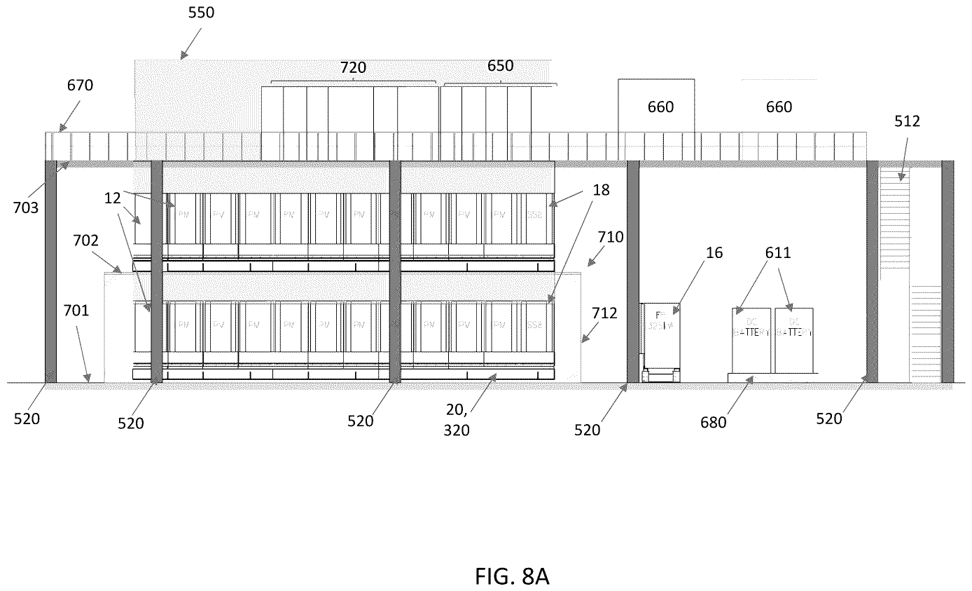

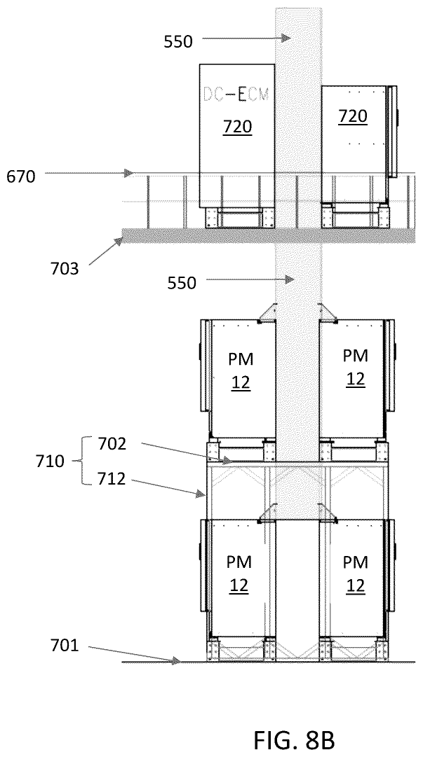

The data center 620 may be collocated with the power generation system 610 in the same multi-level structure, such as a building or an outdoor structure described above or in a structure describe further with respect to FIGS. 7A-7C and 8A-8B below.

FIG. 7A is a top view or plan view of a first level of a first floor 701 of a multi-level structure 700 configured to support power generation system 610 and data center 620. The first level 701 may comprise a ground level of an outdoor structure or a floor of an indoor structure (e.g., building). On the first level 701, the fuel cell power modules (PM6) 12 and the power conditioning modules (SS8) 18 may be arranged in a plurality of rows. For example, four rows are shown. Each pair of rows may share a common exhaust duct 550 or 552 and may be located on the same base 20, 320.

The step load modules (SL7) 306 may be arranged on a common base 680 in a pair of rows which extend parallel to the rows of PMs 12. DC electrical control modules (ECM) 720 may be located on the ends of the rows of step load modules 306. The battery modules 611 and the DC/DC converter modules 615 may be arranged in a separate row on separate base from the PMs 12 and optionally separate from the step load modules 306. In one embodiment, the FPMs 16 may be arranged in a separate row on a separate base from the PMs 12. The FPM 16 row may extend perpendicular to the PM 12 rows between the ends of the PM 12 rows and the row of battery modules 611 and the DC/DC converter modules 615. Servicing aisles 560 may be located between the rows on the first level.

FIG. 7B illustrates a second level 702 of the structure 700. The second level 702 may be located above the first level 701 of FIG. 7A. The second level 702 may comprise a top surface of metal racks 710 that stand on the first level (e.g., ground floor) (e.g., as shown in FIGS. 8A and 8B). The metal racks 710 may be located over the module rows on the first level 701 and have support posts 712 that stand on (and may be fixed to) the floor (e.g., ground or floor of a building) on the first level 701. The support posts 712 may be located to the sides of the modules on the first level 701. No servicing aisles 560 are located on the metal racks 710 on the second level 702. Instead, the servicing aisles 560 are located on the first level 701 between the metal racks 710. The metal racks 710 may support the same modules (e.g., 12, 16, 18, 306, 611, 615) on the second level 702 in the same layout as in the first level 701. In addition, an extra metal rack 710 may be provided which supports the telemetry cabinet 308 and the water distribution modules 314 which are elevated above the first level 701.

FIG. 7C illustrates a third level 703 of the structure 700. The third level 703 may be a structural platform located above the ground or the floor of the structure 700 that includes the first level 701 and the second level 702 of FIGS. 7A and 7B, respectively. The third level 703 platform may have an “L” shape which exposes a part of the first and second levels (701, 702) below.

The third level 703 may support a data center 620 including server racks 630 which may be powered by the power generation system 610 located on the first and the second levels. The AC PDU 640 cabinets and the DC PDU 650 cabinets may also be located on the third level 703 and electrically connected to the power generation system 610 located below. Supporting DC ECMs 720 for power control for the server racks 630 may also be located on the third level 703. Additional water distribution modules 314 may also be located on the third level 703 for the cooling rack 635, and additional telemetry cabinet 308 may be provided to support the server racks 630 and provide communication between the server racks 630 and the power generation system 610 located below. The cooling rack 635 may be integrated with the rows of server racks 630 as part of a containerized data center 620. Specifically, the server racks 630 and optionally the cooling rack 635 may be located in one or more containers 660, such as shipping containers or storage containers. In one embodiment, the containers 660 may be air conditioned. Servicing aisles 560 are located between the rows of the containers 660 and the rows of the other modules/cabinets 640, 650, 720, 314, 308 on the third level 703. The servicing aisles 560 allow personnel to access the containers 660. The interior spaces of the containers 660 may include additional aisles (not shown) which permit personnel access to the server racks and other data center components located in the containers 660.

FIG. 8A illustrates a side view of system 700 illustrated in FIGS. 7A-7C as viewed along the plane A-A in FIGS. 7A-7C. FIG. 8B illustrates another side view of system 700 as viewed perpendicular to the plane A-A. The third level (e.g., platform) 703 forms a second floor above the ground (or ground floor) of the first level 701. The platform of the third level 703 may be supported by columns 520 secured to the first level 701. The platform of the third level 703 may have a similar structure to the second floor F2 described above with respect to FIGS. 5A-5E.

The third level (e.g., platform) 703 may include a railing 670 for safety of personnel accessing the servicing aisles 560 on the third level 703. The vertical exhaust (e.g., a vertical exhaust duct) 550 extends through all three levels 701, 702, 703 and vents above the modules located on the third level 703. For example, the vertical exhaust 550 may extend through an opening between the metal racks 710 and an overlying opening in the third level (e.g., platform) 703 and extend between and above the DC ECM modules 720 located on the third level 703. The stairs 512 extends from the first level 701 (e.g., ground or building floor) and the third level 703 (e.g., platform) without having access to the second level 702.

Referring to FIGS. 6 to 8B, a system 600 includes a multi-level structure 700, a fuel cell power generation system 610 comprising a plurality of fuel cell power modules 12 and at least one step load module 306 containing supercapacitors located on at least one level (e.g., 701, 702) of the multi-level structure 700, and a data center 620 located on at least one level (e.g., 703) of the multi-level structure 700 and electrically connected to the fuel cell power modules 12 and the at least one step load module 306.

In one embodiment, the data center 620 is located on a different level (e.g., 703) of the multi-level structure 700 from the fuel cell power generation system 610. In one embodiment, the fuel cell power generation system 610 is located on a first level 701 of the multi-level structure, and the data center 620 is located on an overlying level 703 of the multi-level structure located above the first level. As shown in FIGS. 8A and 8B, the fuel cell power generation system 610 is located on the first level 701 and a second level 702 of the multi-level structure 700 which overlies the first level 701, and the data center 620 is located on a third level 703 of the multi-level structure 700 located above the first and the second levels.

In one embodiment, the first level 701 comprises a ground level; the second level 702 comprises a top surface of metal racks 710 that are supported by rack support posts 712 standing on the ground level; and the third level 703 comprises a platform that is supported by columns 520 which are anchored to the ground level.

In one embodiment, the data center 620 comprises a plurality of server racks 630 supporting servers 632 and located in at least one container 660; and the fuel cell power generation system 610 comprises a plurality of rows located on the ground level 701 and on the metal racks 710. Each of the plurality of rows comprises at least one common fuel cell support base (20, 320) supporting the plurality of fuel cell power modules 12 located in respective cabinets, and a respective power conditioning module 18 located in a respective cabinet; and at least one common step load module support base 680 supporting a plurality of the step load modules 306 located in respective cabinets. In one embodiment, the system 600 further comprises vertically extending exhaust ducts 550 fluidly connected to the fuel cell power modules 12 and extending through openings in the metal racks 710 and in the platform 703.

In one embodiment shown in FIG. 6, the system 600 further comprises at least one direct current (DC) power distribution unit (PDU) 650 that electrically connects the fuel cell power modules 12 and the at least one step load module 306 to power shelves 631 of server racks 630 of the data center 620; and at least one alternating current (AC) PDU 640 that electrically connects the fuel cell power modules 12 to AC powered auxiliary components of the data center 620.

In one embodiment, the DC PDU 650 comprises: a DC bus 656; DC lines 613a, 613c, 613d which electrically connect the fuel cell power modules 12 and the at least one step load module 306 to the DC bus 656; and DC connecting lines 637a, 637b which electrically connect the DC bus 656 to the power shelves 631. In one embodiment, the system 600 further comprises at least one battery module 611, and at least one DC/DC converter module 615 which electrically connects the DC PDU 650 to the at least one battery module 611 via DC line 613b.

In one embodiment, the AC PDU 640 comprises: an AC bus 644; an AC line 613e which electrically connects the fuel cell power modules 12 to the AC bus 644; and AC connecting lines 637c which electrically connect the AC bus 644 to the AC powered auxiliary components of the data center 620. In one embodiment, the server racks 630 comprise liquid cooled sever racks; and the AC powered auxiliary components comprise at least one of a data center air conditioning unit 642, at least one AC power shelf 631 of AC powered cooling rack 635, or AC powered control electronics 645.

Fuel cell systems of the embodiments of the present disclosure are designed to reduce greenhouse gas emissions and have a positive impact on the climate.

The arrangements of the fuel cell systems, as shown in the various exemplary embodiments, are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein.

Some elements shown as integrally formed may be constructed of multiple parts or elements, the position of elements may be reversed or otherwise varied, and the nature or number of discrete elements or positions may be altered or varied. Other substitutions, modifications, changes and omissions may also be made in the design, operating conditions and arrangement of the various exemplary embodiments without departing from the scope of the present disclosure. Any one or more features of any embodiment may be used in any combination with any one or more other features of one or more other embodiments.

1. A system, comprising:
a multi-level structure;
a fuel cell power generation system comprising a plurality of power modules and at least one step load module comprising supercapacitors located on the at least one level of the multi-level structure; and
a data center located on the at least one level of the multi-level structure and electrically connected to the fuel cell power generation system.

2. The system of claim 1, wherein the data center is located on a different level of the multi-level structure from the fuel cell power generation system.

3. The system of claim 2, wherein the fuel cell power generation system is located on a first level of the multi-level structure, and the data center is located on an overlying level of the multi-level structure located above the first level.

4. The system of claim 3, wherein the fuel cell power generation system is located on the first level and a second level of the multi-level structure which overlies the first level, and the data center is located on a third level of the multi-level structure located above the first and the second levels.

5. The system of claim 4, wherein:
the first level comprises a ground level;
the second level comprises a top surface of metal racks that are supported by rack support posts standing on the ground level; and
the third level comprises a platform that is supported by columns which are anchored to the ground level.

6. The system of claim 5, wherein:
the data center comprises a plurality of server racks supporting servers and located in at least one container;
the fuel cell power generation system comprises a plurality of rows located on the ground level and on the metal racks;
each of the plurality of rows comprises:
at least one common fuel cell support base supporting a subset of the plurality of fuel cell power modules located in respective cabinets, and a respective power conditioning module located in a respective cabinet; and
at least one common step load module support base supporting a plurality of the step load modules located in respective cabinets.

7. The system of claim 6, further comprising vertically extending exhaust ducts fluidly connected to the fuel cell power modules and extending through openings in the metal racks and in the platform.

8. The system of claim 1, further comprising:
at least one direct current (DC) power distribution unit (PDU) that electrically connects the fuel cell power modules and the at last one step load module to power shelves of server racks of the data center; and
at least one alternating current (AC) PDU that electrically connects the fuel cell power modules to AC powered auxiliary components of the data center.

9. The system of claim 8, wherein the DC PDU comprises:
a DC bus;
DC lines which electrically connect the fuel cell power modules and the at least one step load module to the DC bus; and
DC connecting lines which electrically connect the DC bus to the power shelves.

10. The system of claim 9, wherein the AC PDU comprises:
an AC bus;
an AC line which electrically connects the fuel cell power modules to the AC bus; and
AC connecting lines which electrically connect the AC bus to the AC powered auxiliary components.

11. The system of claim 10, wherein:
the server racks comprise liquid cooled sever racks; and
the AC powered auxiliary components comprise at least one of a data center air conditioning unit, at least one AC power shelf of AC powered cooling rack, or AC powered control electronics.

12. The system of claim 8, further comprising at least one battery module, and at least one DC/DC converter module which electrically connects the DC PDU to the at least one battery module.

13. A system, comprising:
a fuel cell power generation system;
a data center comprising server racks containing servers and power shelves;
at least one direct current (DC) power distribution unit (PDU) that electrically connects the fuel cell power generation system to the power shelves of the server racks of the data center; and
at least one alternating current (AC) PDU that electrically connects the fuel cell power generation system to AC powered auxiliary components of the data center.

14. The system of claim 13, wherein the fuel cell power generation system comprises fuel cell power modules and step load modules comprising supercapacitors that are electrically connected to the DC PDU.

15. The system of claim 14, wherein the DC PDU comprises:
a DC bus;
DC lines which electrically connect the fuel cell power modules and the step load modules to the DC bus; and
DC connecting lines which electrically connect the DC bus to the power shelves.

16. The system of claim 15, wherein the AC PDU comprises:
an AC bus;
an AC line which electrically connects the fuel cell power modules to the AC bus; and
AC connecting lines which electrically connect the AC bus to the AC powered auxiliary components.

17. The system of claim 16, wherein:
the server racks comprise liquid cooled sever racks; and
the AC powered auxiliary components comprise at least one of a data center air conditioning unit, at least one AC power shelf of AC powered cooling rack, or AC powered control electronics.

18. The system of claim 14, further comprising at least one battery module, and at least one DC/DC converter module which electrically connects the DC PDU to the at least one battery module.

19. The system of claim 14, wherein:
the fuel cell power generation system is located on at least one level of a multi-level structure; and
the data center is located on a different level of the multi-level structure from the fuel cell power generation system.

20. The system of claim 19, wherein the fuel cell power generation system is located on a first level of the multi-level structure, and the data center is located on an overlying level of the multi-level structure located above the first level.
